(19) United States
(12) Patent Application Publication
(10) Pub. No.: US 2007/0248840 A1
(43) Pub. Date: Oct. 25, 2007

(54) ORGANIC ELECTROLUMINESCENT DEVICE

(75) Inventors: Sherry LIN, Pingtung City (TW); Gwo Sen LIN, Taichung City (TW); Chi Min CHEN, Taichung County (TW); Wei Shan MA, Taichung County (TW)

Correspondence Address: LOWE HAUPTMAN HAM & BERNER, LLP, 1700 DIAGONAL ROAD, SUITE 300, ALEXANDRIA, VA, 22314, US

(73) Assignee: WINTEK CORPORATION, Taichung (TW)

(21) Appl. No.: 11/736,967

(22) Filed: Apr. 18, 2007

(30) Foreign Application Priority Data
Apr. 20, 2006 (TW) 095114069

(51) Int. Cl. H01L 51/54; H01L 51/56; C09K 11/06

(52) U.S. Cl. 428/690; 428/917; 313/504; 313/506; 257/40; 257/102; 257/103; 257/E51.031; 257/E51.032; 257/E51.035; 257/E51.029; 252/301.35; 427/66

(57) ABSTRACT

The present invention relates to an organic electroluminescent device with a light-emitting layer, the light-emitting layer comprising a photo-crosslinkable conductive polymeric host material suitable for facilitating full-color display by spin coating; and at least one small-molecule light-emitting material to achieve high power efficiency. The color-purity of device of the present invention is independent of the distribution of molecular weight of the polymer in the light-emitting layer.

### CROSS REFERENCE TO RELATED APPLICATION

This application claims the priority benefit of Taiwan Patent Application Serial Number 095114069 filed Apr. 20, 2006, the full disclosure of which is incorporated herein by reference.

### BACKGROUND OF THE INVENTION

1. Field of the Invention

The present invention relates to an organic electroluminescent device and, more particularly, to a polymeric electroluminescent device with a light-emitting layer including a conductive polymeric host material whose functional groups on the main or side chains include photo-crosslinkable groups, and at least one small-molecule light-emitting material.

2. Description of Related Art

Flat panel displays constructed with polymeric electroluminescent devices have the advantage of low cost, long lifetime, excellent shock-resistance, fast response, wide view angle, low driving voltage, small thickness and enlarged size. The light-emitting layer and carrier-transporting layer of the polymeric electroluminescent device are made from the conductive conjugate polymer as a major material. In contrast, organic electroluminescent devices mainly use small-molecule dye. As compared with organic electroluminescent devices with small-molecule dyes as the light-emitting material, although the polymeric electroluminescent devices with conductive conjugate polymers have the advantage of low driving voltage and large size, they still have the disadvantage of low lighting efficiency. For manufacturing, the displays of small-molecule material require expensive vacuum evaporation equipment to form the devices. In contrast, an inkjet printing method can be applicable for those with the polymer material because the polymer material is soluble. In the inkjet printing method, the material for the respective light-emitting layer of red, green and blue primary colors can be printed precisely onto a predetermined pattern of subpixels. This will lead to the possibility of independent light emission with individual primary colors. Independent light emission, as known in the art of full color technology, can achieve highest lighting efficiency so that it can provide a desirable approach to overcoming the shortcoming mentioned above for polymeric electroluminescent devices. However, the inkjet printing method is quite expensive. The spin coating method is much simpler and cheaper than other methods but has a difficulty in positioning the three primary colors. On the other hand, conductive conjugate polymers used in conventional polymeric electroluminescent devices require the strict request on distribution of their molecular weight for achieving the purpose of light emission. An appropriate distribution is helpful to the color purity, but makes the fabricating processes more difficult.

The organic electroluminescent device typically has a multi-layered structure supported by a substrate. The structure includes a light-emitting layer sandwiched between two carrier-transporting layers, which are, in turns, positioned between a cathode and an anode. Electrons and holes under forward bias are injected from the respective electrodes into the respective carrier-transporting layers and then move to the light-emitting layer for recombination to form exciton. Excitons are formed as a result of the recombination with energy released and transferred to excite the light-emitting molecules. The excited molecules are de-excited to the ground state in association with light emitting. As known in the art, the typical basic structure may be subject to any appropriate modification. For example, U.S. Pat. No. 6,933,522 discloses a similar structure that further includes an electron-injecting layer adjacent to the cathode. However, because this electroluminescent device needs polymeric material for light emitting, the lighting efficiency is therefore lower in comparison with that using small-molecule material. Furthermore, the spin coating can not improve the full color technology. Indeed, such structural modification of these devices has no contribution to the lighting efficiency and color positioning for the polymeric electroluminescent devices.

Recently, certain organic materials have been proposed. Mixing small-molecule light-emitting material with polymeric host material in the light-emitting layer to serve as a better light-emitting source was disclosed in U.S. Pat. Nos. 6,784,016, 6,870,198 and 6,843,937. But, these inventions still require the inkjet printing technology.

Moreover, U.S. Pat. No. 6,814,887 disclosed a polymeric electroluminescent device and a method thereof, wherein a composition of photo-crosslinkable polymers is used to form the light-emitting layer. Macromol. Rapid Commun. 20 224 (1999), 21 583 (2000) and 35 2426 (2002) are also referred to in this respect. Such a composition of polymers can be selectively cured by photo-crosslinking on predetermined pattern of subpixels with the uncured portion removed by organic solvent. Such a composition of polymers may have its transport property of the carriers, e.g., the mobility, unchanged after being photo-crosslinked. Thus, the properties with respect to photo-crosslinking tend to be exercised in connection with the use of spin coating method, thereby providing an inexpensive and effective full color technology for the displays. Detailed description, for example, is described in Becker, et al, SID 03 Digest, pp. 1286-1289. However, the lighting efficiency obtained in this way fails to be better than those of current technology. Further, the distribution of molecular weight for the composition used in the light-emitting layer is still subject to a strict requirement.

Therefore, there is a need to provide an organic electroluminescent device for allowing full color performance by spin coating, having higher lighting efficiency and rendering the color purity unaffected by the distribution of molecular weight for the material used in the light-emitting layer.

### SUMMARY OF THE INVENTION

It is an object of the present invention to provide a polymeric electroluminescent device that can facilitate full-color displaying by spin coating.

It is another object of the present invention to provide a polymeric electroluminescent device that can achieve higher power efficiency.

It is a further object of the present invention to provide a polymeric electroluminescent device of which the color purity is unaffected by the distribution of molecular weight of the polymer in the light-emitting layer.

In order to achieve the above objects, the present invention provides a polymeric electroluminescent device, supported by a substrate and having an organic light-emitting diode (OLED) disposed between a first and a second electrodes. The OLED includes at least a light-emitting layer having a conductive polymeric host material whose functional groups on the main or side chains include photo-crosslinkable groups such as for the host material to be selectively cured by photo-crosslinking, and at least one small-molecule light-emitting material, which may receive energy from the excited host material and emit light. In the polymeric electroluminescent device according to the present invention, the polymeric host material is not substantially the light-emitting source but provides the specific electrical conduction. Thus, the distribution of molecular weight of the polymer does not affect the color purity. Moreover, in the polymeric electroluminescent device according to the present invention, the conductive property of the polymeric host material does not substantially change after photo-crosslinking.

In the polymeric electroluminescent device according to the present invention, the at least one small-molecule light-emitting material can emit light as it receives energy from the host material that undergoes excitation and de-excitation by energy transferring or carrier trapping.

Another aspect of the present invention is to provide a method for forming a polymeric electroluminescent device. The method includes the steps of: disposing a conductive polymeric host material mixed with at least one small-molecule light-emitting material on a plurality of subpixels, wherein the functional groups on the main or side chains of the host material include photo-crosslinkable groups and the at least one small-molecule light-emitting material emits light as it receives energy from the host material; selectively curing the portion of the host material on a predetermined plurality of subpixels by photo-crosslinking; and removing the uncured portion of the host material mixed with the at least one small-molecule light-emitting material.

In the method according to the present invention, the conductive polymeric host material and the at least one small-molecule light-emitting material can be mixed in a solvent, in particular an organic solvent.

In the method according to the present invention, the uncured portion of the host material mixed with the at least one small-molecule light-emitting material can be removed by washing with a solvent, in particular an organic solvent.

In the method according to the present invention, the host material is sequentially mixed with the at least one small-molecule light-emitting materials of an individual primary color and selectively cured on a predetermined plurality of subpixels to form the respective light-emitting layer, thereby obtaining the light-emitting layers of all the primary colors and achieving full color display.

In the method according to the present invention, the host material mixed with the at least one small-molecule light-emitting material can be applied to a plurality of subpixels by spin coating.

According to one embodiment of the present invention, the polymeric electroluminescent device includes: a substrate; a first electrode formed on the substrate; a hole-transporting layer formed on the first electrode; a light-emitting layer formed on the hole-transporting layer, the light-emitting layer having a conductive polymeric host material, wherein the functional groups on the main or side chains of the host material include photo-crosslinkable groups such as for the host material to be selectively cured on a predetermined plurality of subpixels by photo-crosslinking with the uncured portion removed, and having at least one small-molecule light-emitting material, which may receive energy from the excited host material and emit light; a hole-blocking layer, formed on the light-emitting layer; an electron-transporting layer, formed on the hole-blocking layer; an electron-injecting layer, formed on the hole-blocking layer; and a second electrode, formed on the electron-injecting layer.

According to the embodiment of the present invention, the content of the at least one small-molecule light-emitting material in the light-emitting layer is about 0.001% to about 50% by weight.

According to the embodiment of the present invention, further material can be mixed in the light-emitting layer for matching the energy barriers and improving the thermal stability and film-forming performance.

According to the embodiment of the present invention, the material in the electron-transporting layer can be used for matching the energy barriers and improving the thermal stability and film-forming performance.

Other objects, advantages, and novel features of the present invention will become more apparent from the following detailed description with certain embodiments in conjunction with the accompanying drawings.

### BRIEF DESCRIPTION OF THE DRAWINGS

FIG. 1 is a schematic cross-section view of the structure of the polymeric electroluminescent device according to one embodiment of the present invention.

FIG. 2A-2I show the processes of fabricating the light-emitting layers of respective electroluminescent devices with respective colors in the embodiment described in FIG. 1 as being applied on a substrate with the corresponding plurality of subpixels.

### DETAILED DESCRIPTION OF THE PREFERRED EMBODIMENT

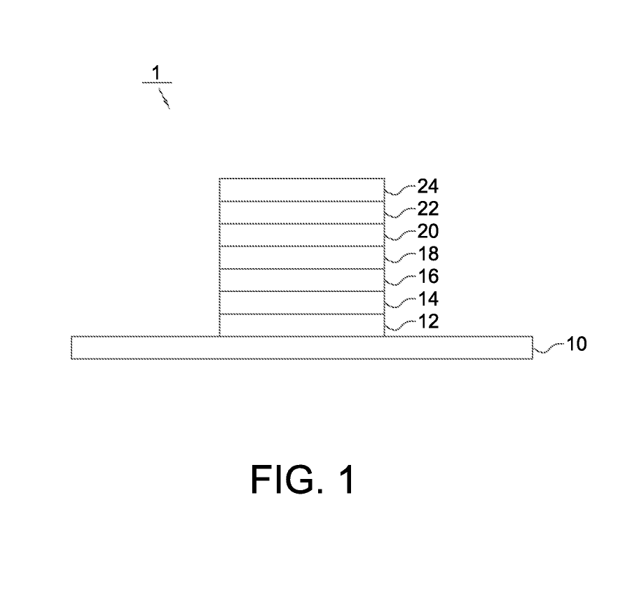

Referring to FIG. 1, it illustrates the structure according to an embodiment of the present invention. A first electrode 12 is formed on a substrate 10. A hole-transporting layer 14 is formed on the first electrode 12. A light-emitting layer 16 is formed on the hole-transporting layer 14. A hole-blocking layer 18 is formed on the light-emitting layer 16. An electron-transporting layer 20 is formed on the hole-blocking layer 18. An electron-injecting layer 22 is formed on the electron-transporting layer 20. A second electrode 24 formed on the electron-injecting layer 22.

According to one embodiment of the present invention, the substrate 10 is made of suitable glass, such as quartz glass, soda-lime glass or flexible material. The material used for the first electrode 12 is such as, for example, indium-tin oxide (ITO), indium-zinc oxide (IZO), aluminum-zinc oxide (AZO) and the like that has a thickness in a range from about 50 nm to about 600 nm. The hole-transporting layer 14 uses a suitable conductive polymeric material, e.g., polyaniline, PEDOT/PSS produced by Bayer AG, which is an aqueous dispersion of poly(3,4-ethylenedioxythiophene)/poly(styrenesulfonate), and the like that has a thickness in a range from about 0.5 nm to about 250 nm.

The host material for the light-emitting layer 16 may be poly(p-phenylenevinylene) (PPV), polyvinylcarbazole (PVK), poly{2,7-[9,9-di(alkyl)fluorine]} or poly(alkylthiophene)derevatives, all of which are single-layer conductive polymer with photo-crosslinkable groups included in the functional groups on the main or side chains. The light-emitting material for the light-emitting layer 16 may be at least one small-molecule light-emitting dye, such as a blue light-emitting material 4,4′-bis[2-(4-(N,N-diphenylamino)phenyl)vinyl]biphenyl (DPAVBi), IDE 102 produced by Idemitsu (Japan) and the like, a green light-emitting material 10-(2-Benzothiazolyl)-2,3,6,7-tetrahydro-1,1,7,7-tetramethyl-1H,5H,11H-(1)-benzopyropyrano(6,7-8-i,j)quinolizin-11-one (C545T) and the like, and a red light-emitting material 4-(Dicyanomethylene)-2-t-butyl-6-(1,1,7,7-tetramethyljulolidyl-9-enyl)-4H-pyran (DCJTB) and the like. The host material and the light-emitting material may be mixed in a solvent, in particular in an organic solvent. The color purities of those red light-emitting materials in state of the art are not ideal. For example, as DCJTB deviates towards orange color, it may be used together with rubrene to have a color shift to red. The light-emitting layer 16 may have further material mixed therein, which is such as Tris(8-hydroxyquinoline)aluminum (Alq3), 1,2,4-triazole-3-alanine (TAZ), Bis(2-methyl-8-quinolinolato-N1,O8)-(1,1′-Biphenyl-4-olato)aluminum (Balq), 2-(4′-biphenyl)-5-(4″-tert-butylphenyl)-1,3,4-oxadiazole (PBD) and the like for matching the energy barriers and improving the thermal stability and film-forming performance. In the method of forming the light-emitting layer 16 for the polymeric electroluminescent device according to the present invention, the uncured portion of the host material mixed with the at least one small-molecule light-emitting material may be removed by washing with a solvent, in particular with an organic solvent. The light-emitting layer 16 may have a thickness in a range from about 0.5 nm to about 250 nm. The content of the at least one small-molecule light-emitting material in the light-emitting layer 16 is from about 0.001% to about 50% by weight.

The hole-blocking layer 18 may use small-molecule materials such as 2,9-dimethyl-4,7-diphenyl-1,10-phenanthroline (BCP), 2,2′,2″-(1,3,5-benzenetriyl)-tris(1-phenyl-1H-benzimi-dazole (TPBI) and the like, or polymeric materials such as poly(9,9-dioctyl-fluorene)/poly[9,9-dioctylfluorene-co-bis-N-(4-butylphenyl)diphenylamine] (F8/TFB) and the like, with a thickness in a range from about 0.5 nm to about 100 nm.

The electron-transporting layer 20 may use Alq3, TAZ, BAlq, PBD and the like with a thickness in a range from about 0.5 nm to about 200 nm, for matching the energy barriers and improving the thermal stability and film-forming performance.

The electron-injecting layer 22 may be made of lithium fluoride, strontium fluoride, strontium, lithium and the like, with a thickness in a range from about 0.01 nm to about 200 nm.

The second electrode 24 may be a single-layer structure made of aluminum, silver and the like, or a multi-layer comprising, such as, calcium/aluminum, barium/aluminum, calcium/magnesium: aluminum, barium/magnesium: aluminum and the like.

### EXAMPLE

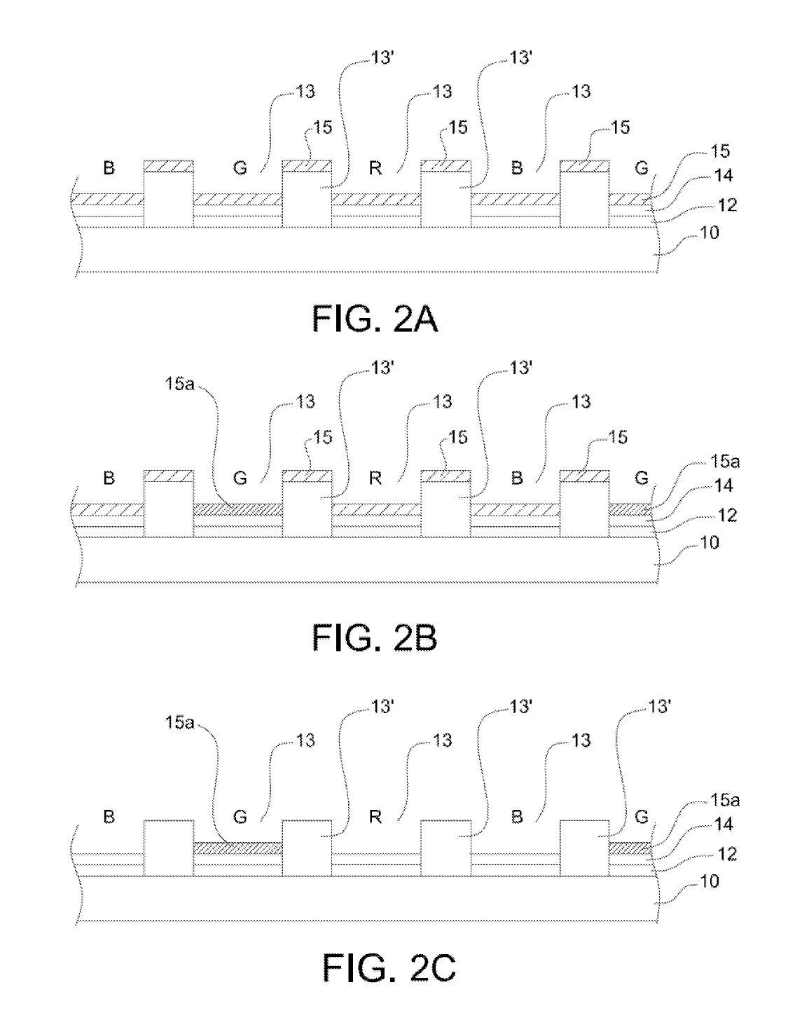

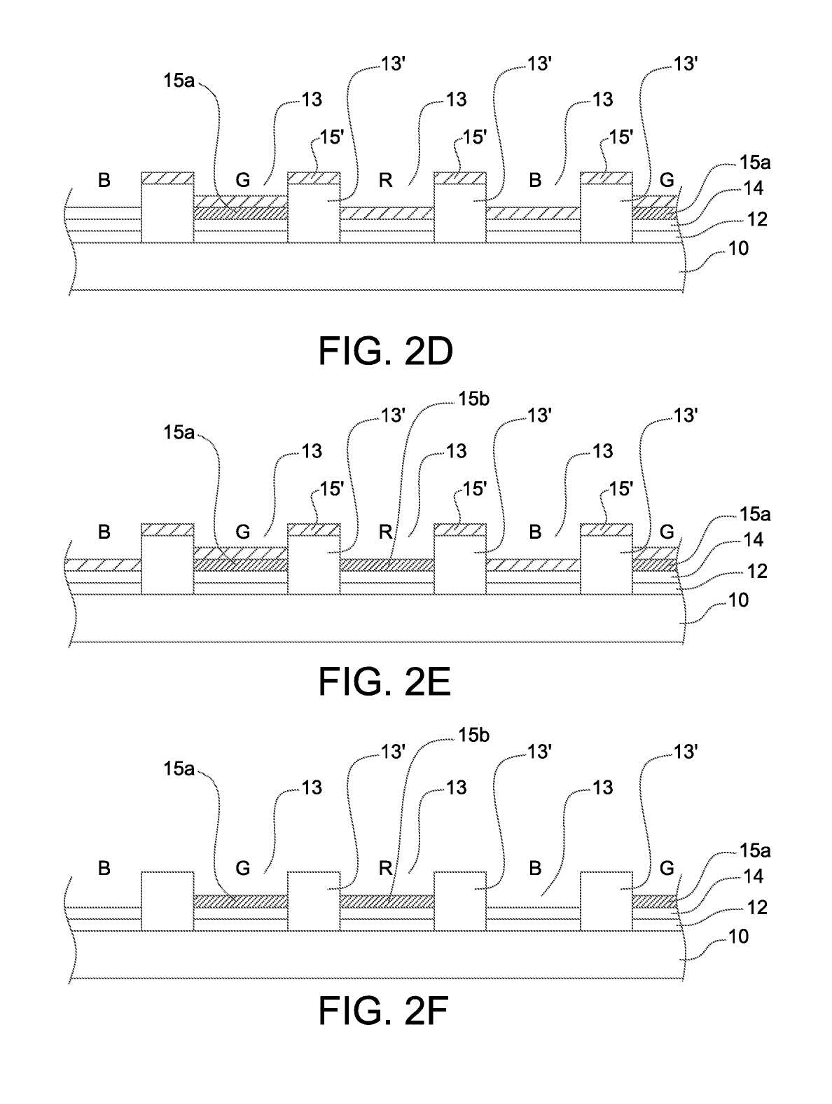

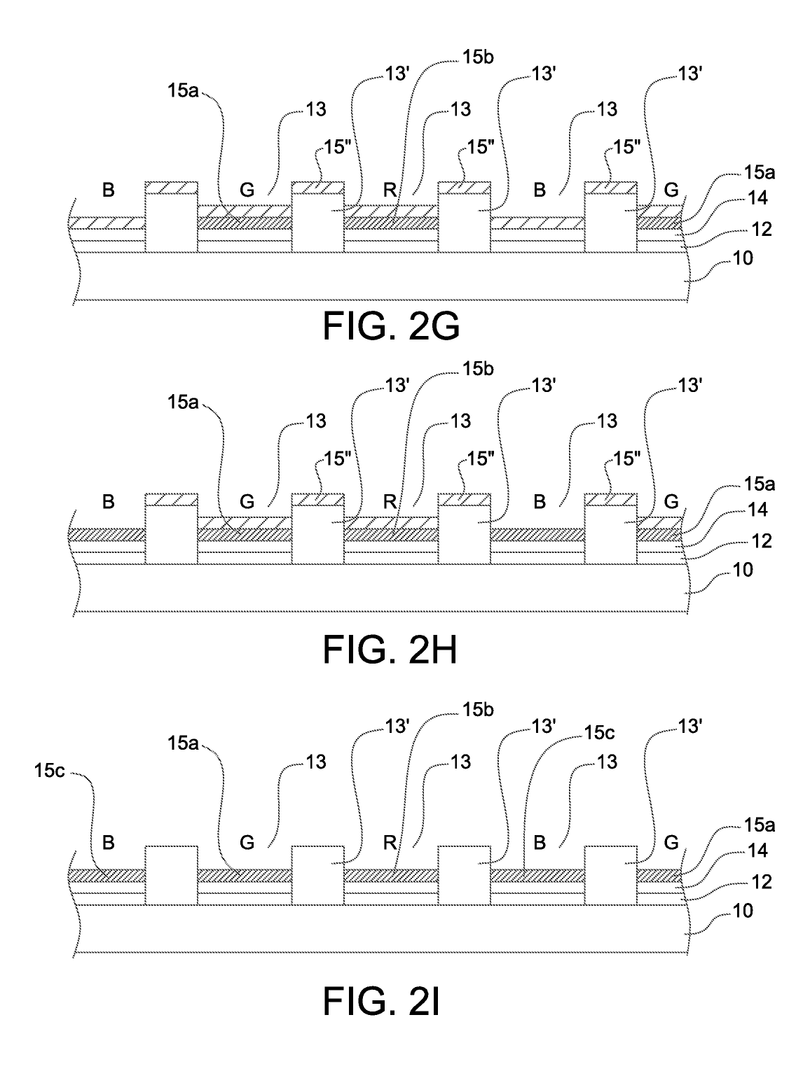

A full-color display device according to the embodiment described above may be made in the following steps (referring to FIG. 2A-2I):

Washing the substrate 10 and the first electrode 12 formed thereon by means of supersonic cleaning with an organic solvent or de-ionized water, nitrogen blowing, vacuum drying at a temperature ranging from about 80° C. to about 200° C., UV ozone stripping and oxygen plasma stripping.

A plurality of subpixels is formed by coating a photo-sensitive insulating polymeric material onto the substrate 10 and the first electrode 12. The patterned photo-sensitive insulating polymeric material is formed by the photolithography process. A plurality of subpixels with apertures 13 and spacers 13′ is formed and each subpixel corresponds to an organic electroluminescent device.

The hole-transporting layer 14 is formed by spin coating PEDOT/PSS and then is baked in an inert gas atmosphere.

The light-emitting layer 16 is formed by spin coating the green light-emitting material 15, which has been dissolved in a suitable amount of xylene. The green light-emitting material 15 includes PVK, C545T amounting to about 2% by weight for light-emitting, and Alq3 amounting to about 20% by weight for matching the energy barriers and improving the thermal stability and film-forming performance (referring to FIG. 2A); selectively curing the green light-emitting material 15 on a predetermined plurality of subpixels by photo-crosslinking, as a result of the irradiation of UV through a specific photo mask on the coating (Refer to FIG. 2B); removing the uncured portion of the green light-emitting material 15 by washing with xylene to form a green light-emitting layer 15a (Refer to FIG. 2C); and forming a red light-emitting layer 15b on the structure with the green light-emitting layer 15a formed in a similar way (Refer to FIG. 2D-2F). A blue light-emitting layer 15c is formed on the structure with the green and red light-emitting layers 15a and 15b formed in a similar way (referring to FIG. 2G-2I). The red light-emitting material 15′ includes PVK, DCJTB (about 3.5%) plus rubrene (about 15%) for light-emitting, and Alq3 (about 15%) for matching the energy barriers and improving the thermal stability and film-forming performance. The blue light-emitting material 15″ includes PVK, IDE 102 (about 5%) for light-emitting, and TC1552 (about 15%) produced by Tetrahedron Technology Co. (Miao-Li County Taiwan) for matching the energy barriers. The green, red and blue light-emitting layers 15a, 15b and 15c are baked in an inert gas atmosphere.

The subsequent layers, i.e., the hole-blocking layer 18, the electron-transporting layer 20, the electron-injecting layer 22 and the second electrode 24 are formed by vacuum evaporation. The material for the hole-blocking layer 18 is TBPI, the material for the electron-transporting layer 20 is Alq3, the material for the electron-injecting layer 22 is lithium fluoride and the material for the second electrode 24 is aluminum.

A water/oxygen-barrier thin film is formed on the second electrode 24 by vacuum evaporation. A glass cover plate is disposed on the film with the sides configured by the substrate 10. The cover plate is coated with seal and is cured by heating in order to form a package.

After the package is formed, it is then tested. A luminescence meter PR 650 produced by PhotoResearch is used to read out the data for the present embodiment and a typical software for measuring OLED's photonic characteristics is used to analyze the data.

The following tables provide a comparison of the result with that set forth in the report by Becker, et al, SID 03 Digest, pp. 1286-1289. Table 1 compares the power efficiencies of the electroluminescent devices for the three primary colors, where the power efficiency is defined as the ratio of the luminous flux to the power consumed under current density of 50 mA/cm². Table 2 compares the luminescences.

TABLE 1

| | G | R | B |
|---|---|---|---|
| the present invention | 6.5 | 1.9 | 3.1 |
| Becker et al | 4.88 | 0.69 | 2.08 |

Unit: lm/W, under current density of 50 mÅ/cm²

TABLE 2

| | G | R | B |
|---|---|---|---|
| the present invention | <2500 | <2500 | <2500 |
| Becker et al | 8000 | 2500 | 4000 |

Unit: cd/m², under current density of 50 mÅ/cm²

Moreover, the CIE chromaticity coordinates of the electroluminescent devices for the three primary colors are (0.30, 0.63) for the green, (0.65, 0.35) for the red and (0.15, 0.27) for the blue.

Accordingly, in the polymeric electroluminescent device of the present invention that may be obtained by spin coating for full color displaying because its transport property of the carriers is unchanged after photo-crosslinking. The polymeric host material for the light-emitting layer is not substantially the light-emitting source so that its distribution of molecular weight does not affect the color purity and. Furthermore, the at least one small-molecule light-emitting material may emit light as it receives energy from the host material that undergoes excitation and de-excitation by energy transferring or carrier trapping.

While the invention has been described in detail with certain preferable embodiments, this description is not intended to limit the invention for which other embodiments may be possibly employed. It is to be understood that many other possible modifications and variations can be made by those skilled in the art without departing from the spirit and scope of the invention as hereinafter claimed.

What is claimed is:

1. An organic electroluminescent light-emitting layer, comprising:
a host material of conductive polymers whose functional groups on the main or side chains include photo-crosslinkable groups; and
at least one light-emitting material, mixed with the host material.

2. The organic electroluminescent light-emitting layer of claim 1, wherein the host material is selected from the group consisting of poly(p-phenylenevinylene) (PPV), polyvinylcarbazole (PVK), poly{2,7-[9,9-di(alkyl)fluorine]} and poly(alkylthiophene)derivatives.

3. The organic electroluminescent light-emitting layer of claim 1, wherein the at least one light-emitting material is a green light-emitting material.

4. The organic electroluminescent light-emitting layer of claim 3, wherein the green light-emitting material comprises 10-(2-Benzothiazolyl)-2,3,6,7-tetrahydro-1,1,7,7-tetramethyl-1H,5H,11H-(1)-benzopyropyrano(6,7-8-i,j )quinolizin-11-one (C545T).

5. The organic electroluminescent light-emitting layer of claim 1, wherein the at least one light-emitting material is a red light-emitting material.

6. The organic electroluminescent light-emitting layer of claim 5, wherein the red light-emitting material comprises 4-(Dicyanomethylene)-2-t-butyl-6-(1,1,7,7-tetramethyljulolidyl-9-enyl)-4H-pyran (DCJTB).

7. The organic electroluminescent light-emitting layer of claim 5, wherein the red light-emitting material further comprises rubrene.

8. The organic electroluminescent light-emitting layer of claim 1, wherein the at least one light-emitting material is a blue light-emitting material.

9. The organic electroluminescent light-emitting layer of claim 8, wherein the blue light-emitting material comprises 4,4′-bis[2-(4-(N,N-diphenylamino)phenyl)vinyl]biphenyl (DPAVBi).

10. The organic electroluminescent light-emitting layer of claim 1, wherein the content of the at least one small-molecule light-emitting material is from about 0.001% to about 50% by weight.

11. An organic electroluminescent device, comprising:
a substrate;
a first electrode, formed on the substrate;
an organic light-emitting diode, formed on the first electrode, the organic light-emitting diode having at least a light-emitting layer, wherein the light-emitting layer comprises a conductive polymeric host material whose functional groups on the main or side chains include photo-crosslinkable groups and at least one light-emitting material, which is mixed with the host material; and
a second electrode, formed on the organic light-emitting diode.

12. The organic electroluminescent device of claim 11, wherein the organic light-emitting diode further comprises:
a hole-transporting layer, formed between the first electrode and the light-emitting layer;
a hole-blocking layer, formed on the light-emitting layer;
an electron-transporting layer, formed on the hole-blocking layer; and
an electron-injecting layer, formed on the electron-transporting layer.

13. The organic electroluminescent device of claim 11, wherein the host material is selected from the group consisting of poly(p-phenylenevinylene) (PPV), polyvinylcarbazole (PVK), poly{2,7-[9,9-di(alkyl)fluorine]} and poly(alkylthiophene)derivatives.

14. The organic electroluminescent device of claim 11, wherein the at least one light-emitting material is a green light-emitting material.

15. The organic electroluminescent device of claim 14, wherein the green light-emitting material comprises 10-(2-Benzothiazolyl)-2,3,6,7-tetrahydro-1,1,7,7-tetramethyl-1H,5H,11H-(1)-benzopyropyrano(6,7-8-i,j )quinolizin-11-one (C545T).

16. The organic electroluminescent device of claim 11, wherein the at least one light-emitting material is a red light-emitting material.

17. The organic electroluminescent device of claim 16, wherein the red light-emitting material comprises 4-(Dicyanomethylene)-2-t-butyl-6-(1,1,7,7-tetramethyljulolidyl-9-enyl)-4H-pyran (DCJTB).

18. The organic electroluminescent device of claim 11, wherein the at least one light-emitting material is a blue light-emitting material.

19. The organic electroluminescent device of claim 18, wherein the blue light-emitting material comprises 4,4′-bis[2-(4-(N,N-diphenylamino)phenyl)vinyl]biphenyl (DPAVBi).

20. The organic electroluminescent device of claim 11, wherein the content of the at least one small-molecule light-emitting material is from about 0.001% to about 50% by weight.

21. A method of forming a polymeric electroluminescent device, comprising the steps of:
disposing a conductive polymeric host material mixed with at least one small-molecule light-emitting material on a plurality of subpixels, wherein the functional groups on the main or side chains of the host material include photo-crosslinkable groups, the at least one small-molecule light-emitting material emits light as it receives energy from the host material;
selectively curing the portion of the host material on a predetermined plurality of subpixels by photo-crosslinking; and
removing the uncured portion of the host material mixed with the at least one small-molecule light-emitting material.

22. The method of claim 21, wherein the host material and the at least one small-molecule light-emitting material are mixed in a solvent.

23. The method of claim 21, wherein the uncured portion of the host material mixed with the at least one small-molecule light-emitting material is removed by washing with a solvent.

24. The method of claim 21, wherein the host material is sequentially mixed with the at least one small-molecule light-emitting materials of an individual primary color and selectively cured to form the respective light-emitting layer on a predetermined plurality of subpixels.

25. The method of claim 21, wherein the host material mixed with the at least one small-molecule light-emitting material is applied to a plurality of subpixels by spin coating.

26. The method of claim 22, wherein the solvent is an organic solvent.

27. The method of claim 23, wherein the solvent is an organic solvent.
